(19) United States
(12) Patent Application Publication
(10) Pub. No.: US 2006/0145190 A1
(43) Pub. Date: Jul. 6, 2006

(54) Surface passivation for III-V compound semiconductors

(76) Inventors: David B. Salzman, Chevy Chase, MD (US); Aristo Yulius, Hamden, CT (US); An Chen, Sunnyvale, CA (US); Jerry M. Woodall, West Point, IN (US); Eric Harmon, Norfolk, MA (US)

Correspondence Address: Dr. Dave S. Garrod, Esq.;Goodwin-Procter, 599 Lexington Avenue, New York, NY, 10022, US

(21) Appl. No.: 11/323,882

(22) Filed: Dec. 30, 2005

Related U.S. Application Data
(60) Provisional application No. 60/640,723, filed on Dec. 31, 2004.

(51) Int. Cl. H01L 31/0328

(52) U.S. Cl. 257/192

(57) ABSTRACT

A structure and method of fabrication are disclosed for improving surface passivation of III-V compound semiconductors. The invention exploits certain anion-rich compound semiconductors to form a high quality interface with a dielectric when anion mobility is increased during an annealing step. Low post-annealing surface state densities result in a low fixed charge density at the interface and low surface recombination velocities. The invention enables microelectronic devices including diode, transistor, solar cell, photodetector, and CCDs with superior performance wherever prior art devices have inferior surface passivation.

Priority is entitled from U.S. Pat. App. No. 60/640,723, filed Dec. 31, 2004. The U.S. government may have certain rights under this application in accordance with contract W31P4Q-04-C-R309.

### FIELD OF THE INVENTION

This invention relates generally to the field of passivating surfaces of compound semiconductors, and more particularly to the design and fabrication of insulator-semiconductor interfaces suitable for use as passivating layers to reduce surface generation and recombination effects. It applies especially to bipolar devices such as photodiodes and bipolar junction transistors (BJTs), including heterojunction bipolar transistors (HBTs); metal-insulator-semiconductor (MIS) structures, including metal-insulator-semiconductor field-effect transistors (MISFETs) and related field-effect transistors; charge coupled devices (CCDs); and field plates and MIS guard ring structures used for applications such as high voltage Schottky diodes and avalanche photodiodes.

### BACKGROUND OF THE INVENTION AND LIMITATIONS OF THE PRIOR ART

The invention discloses a new method for passivating a first semiconductor surface when a second material is grown on the first semiconductor; or, equivalently, passivating the first semiconductor's surface when it is grown on the second material. By the term “grow” we refer to the deposition of a material through techniques including molecular beam epitaxy (MBE), liquid-phase epitaxy (LPE), vapor deposition (VD, particularly including chemical VD (CVD), plasma-enhanced CVD (PECVD), jet VD (JVD), and physical VD (PVD)), sputtering, evaporation, vapor transport (VT), or other approaches to crystal growth or semiconductor deposition familiar to materials scientists today or emerging for related purposes in the future. “Passivating” means some combination of achieving a low density of interface states, ensuring that the Fermi level at or near the interface is predominantly unpinned, ensuring that the defect density at or near the surface is not substantially higher than in the bulk material, and/or protecting the surface from damage by oxygen or water.

Consider a first material comprising a compound semiconductor using at least one element from group III of the periodic table (e.g. indium (In), gallium (Ga), aluminum (Al)) and one element from group V of the periodic table (e.g. phosphorous (P), arsenic (As), antimony (Sb), or nitrogen (N)). Consider also a second material including an insulator (e.g. Si₃N₄, polyimide, SiO₂, Al₂O₃, Ga₂O₃) or a semiconductor with a wider band gap than the first material (typically GaP, GaN, SiC, or related materials if the first material is GaAs). The first and second materials can each be amorphous, crystalline, polycrystalline, or some other state.

In the prior art, the density of surface states at and near (i.e. within tens of nm) the surface of the first material is ordinarily high (e.g. above 10¹² cm⁻²), so the Fermi level there is “pinned,” meaning limited to a small energy range. Pinning typically confines the Fermi level to an energy within the forbidden band gap, with the exact Fermi level pinning position dependent on the energy levels associated with surface states. The Fermi level is likewise pinned when the second material is grown directly on the first, except for the case where the second material is similar to the first, such that lattice-mismatch is small and the single crystal structure can be maintained across the interface without generating interface states. The specification for the first and second materials rules out this exception.

The pinning of the Fermi level is problematic for a number of reasons for microelectronic devices formed in the first (or second, or first and second) material(s). For instance, the pinning can distort the band structure in a manner which reduces the efficiency of charge carrier transport and prevents the use of the field effect to achieve transistor action. Generation and recombination rates are also generally increased (both due to the band bending, which causes minority carriers to be swept to the surface, and by the surface states that cause Fermi level pinning, which also act as recombination and generation sites). Such surface generation and recombination generally degrade device performance. The surface recombination rate is commonly quantified in units of surface recombination velocity. High surface recombination velocities correspond to rapid recombination at the surface, hence poor surface passivation. Low surface recombination velocities correspond to low surface recombination rates, hence good surface passivation.

While high quality, low defect-density semiconductor-insulator interfaces are widely available for silicon-based semiconductors, with the Si-to-SiO₂ interface forming the basis of the vast majority of the current semiconductor industry, no such high quality, low defect-density semiconductor-insulator interface exists for III-V compound semiconductors. The availability of a high quality, low defect-density semiconductor-insulator interface for III-V compound semiconductors would lower recombination and generation at such interfaces. Furthermore, such a low defect-density semiconductor-insulator interface would allow an overlying conductor to modulate the Fermi level position in the underlying semiconductor, enabling a wide range of metal-insulator-semiconductor (MIS) structures to be formed, including field-effect devices such as MOSFETs and MISFETs.

For III-V compound semiconductors, no such suitable MIS technology has been developed. This is because most III-V compound semiconductors exhibit very high surface state densities, caused by dangling and frustrated bonds at the surface. Upon exposure to air, compound semiconductor surfaces can oxidize, which generally increases the density of surface states, resulting in stronger Fermi level pinning. Attempts to passivate these dangling and frustrated bonds with in situ or via ex situ passivation techniques have not been generally successful. The high density of surface states at III-V surfaces (including vacuum-cleaved surfaces, surfaces coated with various dielectrics, and oxidized surfaces) results in high recombination and generation rates at the surfaces, and pinning of the Fermi level at the interface: effects which greatly limit the field effect's ability to modulate the Fermi level.

While extensive efforts to find a suitable insulator-semiconductor interface have been attempted, all prior attempts have exhibited one or more of the following (e.g. T Mimura et al., “Status of the GaAs Metal-Oxide-Semiconductor Technology,” IEEE Trans. Electron Devices, ED-27 pp. 1147-115, (1980), J Reed et al., “Characteristics of in situ Deposited GaAs Metal-Insulator-Semiconductor Structures,” Solid-State Electronics, 38, pp. 1351-1357 (1995), DSL Mui et al., “A review of III-V semiconductor based metal-insulator semiconductor structures and devices,” Thin Solid Films 231, pp. 107-124 (1993)):
1. Resulted in too large an interface state density (D A Baglee, D K Ferry, C W Wilmsen, and H H Wideer, “Inversion layer transport and properties of oxides on InAs,” J. Vac. Sci. Technol., 17, p. 1032, and H H Wieder, “Perspectives on III-V compound MIS structures,” J. Vac Sci. Technol., 15, p. 1498, 1978, H A Washburn, J R Sites, and H H Wieder, “Electronic profile of n-InAs on semi-insulating GaAs,” J. Appl. Phys., 50, p. 4872 1979).
2. Used a technology that is not commercially viable or which was not cost effective for commercial applications.
3. Exhibited low reliability

In consequence, prior art III-V semiconductor devices often exhibit lower performance than they would if better-passivated semiconductor-insulator interfaces were available. Symptoms include high interface state density, high surface generation rates, high surface recombination velocities, and surface Fermi level pinning.

Several prior art approaches have been developed which provide partial solutions to the interface problem of III-V semiconductors. Note the terminology: Passivating a surface eliminates or compensates many surface states.

Prior art approach #1: Regrowth. One method of passivating surface states has been to use epitaxy to regrow the second material to try to achieve a single-crystal, lattice-matched, wide band gap semiconductor layer on top of the active surfaces of a device. This is often done for edge-emitting laser structures, where the regrowth provides surface passivation and also optical wave-guiding functionality. However, the high growth temperatures, elaborate surface preparation techniques, and need for extreme cleanliness during the regrowth process has limited this approach to specialty applications such as high performance laser diodes. Furthermore, there are only a limited number of lattice-matched semiconductor compositions, so only a limited range of heterojunctions that can be made with regrowth, and paucity of heterojunctions able to confine free carriers on technologically useful III-V semiconductors.

Prior art approach #2: Due to the difficulty of producing MIS structures in III-V compound semiconductors, prior art approaches have focused on using metal semiconductor (MES) approaches. In this approach, a MES Schottky diode is formed via the deposition of a metal directly on top of the exposed semiconductor surface without the intentional use of an intervening insulator layer. Since the metal is in intimate contact with the surface states, it can be used to modulate the surface Fermi level position directly, which in turn allows modulation of an underlying semiconductor layer such as the channel of a FET, resulting is a metal-semiconductor field-effect transistor (MESFET) structure. Note that the Fermi level pinning at the metal-semiconductor interface is not changed, and the position of the surface Fermi level with respect to the band edges is not changed, even when using different metals with different work functions. The MESFET structure is used for nearly all III-V compound semiconductor FETs, including pseudomorphic high electron mobility transistors (pHEMTs) and modulation-doped field-effect transistors (MODFETs). However, the MES structure generally exhibits some severe limitations, including relatively low Schottky barrier heights, leading to excessive MES diode currents and greatly limiting the range of gate bias voltage, and the inability to invert the surface or channel region. While attempts to improve the Schottky barrier height by inserting a lattice-matched, wide band gap semiconductor between the channel region and the gate may improve the barrier height for certain semiconductor compositions, the approach is not a general solution. In addition, the requirement of lattice-matching (or the requirement that the wide band gap semiconductor be pseudomorphic) limits the range of materials that can be used. For some semiconductors such as InP, the Schottky barrier height of MES is too low because Fermi level pinning in InP occurs near the conduction band edge, resulting in too large a leakage current between the gate and the channel. Furthermore, the MES approach does not result in low recombination and generation rates at the interface, so is not suitable for use in bipolar devices, nor for achieving channel inversion.

Prior art #3 MOSHFET: Recently, Asif Khan, et al. (U.S. Pat. No. 6,690,042, U.S. Pat. App. No. 2002/0052076, U.S. Pat. App. No. 2004/0036086) have developed a concept of the metal-oxide-semiconductor heterostructure field-effect transistor (MOSHFET) using GaN and related compound semiconductors. They describe a method to “prevent current-voltage characteristic collapse at high drain biases due to the large density of interface states” in heterostructure field-effect transistors (HFET). Their technique consists of combining a conventional HFET structure (e.g. AlGaN barrier and GaN channel) with an additional insulator layer (SiO₂, Si₃N₄, etc.), which allows them to achieve very low gate currents and higher gate biases than the HFET structure alone. The inventors of U.S. Pat. No. 6,690,042 also note:
“ . . . the surface charge density in SiO₂ layer, nₛ is estimated to be about 1×10¹² cm⁻². This is one order of magnitude less than the sheet carrier density (of free carriers) in the 2D electron gas channel of the MOSHFET, thereby indicating a high quality for the SiO₂/AlGaN interface.”

However, the MOSHFET approach is not a complete solution, because the surface states between the oxide (or any other insulator) and the semiconductor still affect the performance of the FET. While the MOSHFET has lowered the sensitivity of the FET structure to these interface states by moving the states away from the channel-insulator interface by inserting a wide band gap lattice-matched (or pseudomorphic) semiconductor barrier layer between the channel and the insulator, the barrier-insulator interface states still make important contributions to the fixed oxide charge. The MOSHFET approach also relies on extremely large sheet carrier densities to mitigate the effects of the barrier/insulator interface states, which may not always be optimal, since carrier mobility and confinement often degrade at high sheet carrier densities.

Prior art #4 MOSFET and MISFET approaches: A variety of techniques have been developed to for deposition of oxides and other insulators for MOSFET and MISFET applications (see e.g. C-J Huang, Z-S Ya, J-H Horng, M-P Houng, Y-H Wang, “GaAs Metal-Oxide-Semiconductor Field-effect Transistors Fabricated with Low-Temperature Liquid-Phase-Deposited SiO₂,” Japanese J. Appl. Phys. 41, pp. 5561-5562 (September 2002); Y C Wang, M Hong, J M Kuo, J P Mannaerts, J Kwo, H S Tsai, J J Krajewski, Y K Chen, and A Y Cho, “Demonstration of Submicron Depletion-Mode GaAs MOSFETs with Negligible Drain Current Drift and Hysteresis,” IEEE Electron Device Letters, 20(9), pp. 457-459 (1999), P D Ye et al., “Depletion-mode InGaAs metal-oxide-semiconductor field-effect transistor with oxide gate dielectric grown by atomic-layer deposition,” Appl. Phys. Lett. 84(3), pp. 434-436 (2004), P D Ye et al., “GaAs metal-oxide-semiconductor field-effect transistor with nanometer thin dielectric grown by atomic layer deposition,” Appl. Phys. Letters 83(1), pp. 180-182, (2003), Z Chen and D Gong, “Physical and electrical properties of a Si₃n₄/Si/GaAs metal-insulator-semiconductor structure,” J. Applied Physics 90(8), pp. 4205-4210, (2004); J Reed, “Characteristics of in situ Deposited GaAs Metal-Insulator-Semiconductor structures,” Solid-State Electronics 38(7), pp. 1351-1357 (1995); M Passlack et al., “C-V and G-V Characterization of in situ Fabricated Ga₂O₃-GaAs Interfaces for Inversion/Accumulation Device and Surface Passivation Applications,” Solid-State Electronics 39(8), pp. 1133-1136 (1996); A Jaouad, V Aimez, C Aktik, K Bellatreche, and A Souifi, “Fabrication of (NH₄)₂S passivated GaAs metal-insulator-semiconductor devices using low-frequency plasma-enhanced chemical vapor deposition,” J. Vac. Sci. Technol. A22, p. 1027 (2004)).

It is worth noting that exposure of GaAs (and most other compound semiconductor) surfaces to oxygen causes rapid pinning of the Fermi level. Hale (M J Hale et al., “Scanning tunneling microscopy and spectroscopy of gallium oxide deposition and oxidation of GaAs(001)-c(2×8)/(2×4),” J. Chem. Physics 119(13), (2003)), notes that Fermi level pinning occurs at merely 5% coverage of the GaAs surface with oxygen, highlighting the difficulty of using in situ techniques to achieve a GaAs insulator-semiconductor surface with a low density of surface states since chemisorption of even a small percentage of oxygen causes significant Fermi level pinning. Furthermore, since many approaches use oxides for the insulator, it is likely that there will be a significant amount of oxygen available in the deposition chamber to cause oxidation of the GaAs surface, resulting in a high density of surface states.

One prior art technique to prevent oxidation of the GaAs surface has been to use in situ coating of the GaAs surface with As. While As coating does appear to prevent oxidation of the GaAs surface, the sample must remain in situ (M Passlack, et al., “Nonradiative recombination at GaAs homointerfaces fabricated using an As cap deposition/removal process”, Appl. Phys. Lett. 72(24), pp. 3163-3165 (1998)) to achieve a low interface state density, lest exposure to air cause a rapid increase in the interface state density. Furthermore, the deposition of As on the GaAs surfaces and subsequent desorption of the As prior to forming a surface interface may be incompatible with commercial semiconductor processing procedures.

Another prior art technique to prevent oxidation of the GaAs surface has been to use in situ transfer of the GaAs wafer to the gate insulator deposition chamber maintaining ultra high vacuum conditions until after deposition of the gate insulator. (See M Passlack, M Hong, J P Mannaerts, J R Kow, and L W Tu, “Recombination velocity at oxide-GaAs interfaces fabricated by in situ molecular beam epitaxy,” Appl. Phys. Lett., 68, p. 3605 (1996)). For certain oxides, notably gallium oxide (Ga₂O₃), a low surface recombination velocity can be obtained. However, the complexity of in situ deposition of the oxide, and the stability of gallium oxide have generally prevented this approach from becoming commercially successful.

Others (See C L Chen et al., “Effects of low-temperature-grown GaAs and AlGaAs on the current of a metal-insulator-semiconductor structure,” J. Vac. Sci. Technol. B 14(3), pp 1745-1751 (1996), L-W Yin, J P Ibbetson, M M Hashemi, W Jiang, S-Y Hu, A C Gossard, and U K Mishra, “Study of Transport Through Low-Temperature GaAs MISFETs with LT-GaAs as a Gate Insulator,” Proceedings of the MRS Fall Meeting, 241, pp. 187-192, Boston, Mass. (1992).) have attempted to use LTG-GaAs (LTG-GaAs) and related materials in MISFET structures. These efforts have failed to produce high performance MISFET devices because they used thick, highly defected LTG layers, where the density of traps in the LTG layers was sufficient to cause a large fixed charge density, pinning of the Fermi level mid gap, and high recombination rates.

While some of these techniques have met with limited success and demonstrated modestly low densities of interface states and insulator states, MIS devices using III-V semiconductors have not generally become commercially viable for a number of reasons, including excessive surface state densities and instability of the insulator-semiconductor interface, leading to poor long-term characteristics.

### OBJECTS OF THE INVENTION

In the present invention, unpinning of the surface Fermi level is exploited for semiconductor-insulator interfaces. Passivating the surface of a compound semiconductor lowers the density of surface states, reducing surface recombination effects and allowing fully general positioning of the surface Fermi level. An object of the invention is to form improved field-effect devices (e.g. metal-insulator-semiconductor (MIS) diodes; field-effect transistors (FETs) such as metal-insulator-semiconductor field-effect transistors (MISFETs) or metal-oxide-semiconductor field-effect transistors (MOSFETs); and related FET structures such as modulation doping of the FET channel for MISFET applications and pseudomorphic channels for MISFET applications). Another object of the invention is to improve surface passivation in order to reduce recombination losses at surfaces, which is important for the window passivation of solar cells (U.S. Pat. No. 3,765,026 by Woodall et al., “Converter of Electromagnetic Radiation to Electrical Power,” Jul. 4, 1972), passivation of the exposed surfaces of the base-emitter junction of bipolar transistor structures, including heterojunction bipolar transistor structures, and passivation of surfaces and edges of power diodes using guard ring approaches such as field oxides. Another object is to passivate the surfaces of III-V compound semiconductors generally, in native form, for use in a vacuum. A further object is to passivate the interfaces between compound semiconductors and other (simple or compound) semiconductors, dielectrics, organics, or annealed metals. A further object of the invention to enable high quality, insulator-semiconductor interfaces with low interface state densities when the semiconductor is a compound semiconductor using alloys of Al, Ga, In, As, P, N, or Sb. Such insulator-semiconductor interfaces enable:
Low surface generation and/or recombination currents in bipolar devices such as PN photodiodes, PIN photodiodes, solar cells, bipolar junction transistors, heterojunction bipolar transistors, and other bipolar devices.
Low interface charge densities for MIS devices such as MISFETs, MOSFETs, MOSHFETs, other FET structures using modulation doping and/or pseudomorphic high mobility channels, guard ring structures using field oxide insulation.
Low surface recombination/generation in unipolar devices such as metal semiconductor metal (MSM) photodetectors, including photoconductive photodetectors
Low surface recombination in LEDs and lasers, where surface recombination leads to lower light output efficiency.
High performance CCD devices, where MIS or similar structures are used to transfer charge between various charge wells, typically used for imaging applications.

The present invention passivates the first material at and near its interface with the second material, greatly reducing the effects of pinning. If the second material is a wide band gap semiconductor, the layer may passivate its surface as well (i.e. the invention may passivate states both at the interface between the first material and the second material, and the upper surface of the second material). The invention allows the Fermi level at and near the interface between the passivating layer and the first material to be controlled as a function of the composition and doping of the first material and an externally-applied electrical field, such as can be achieved using the field effect in a metal-insulator-semiconductor (MIS) structure.

Described in the general case, the method first grows a thin passivating layer on the first material, the passivating layer largely comprising a III-V compound semiconductor which is anion-rich with elements from column V of the periodic table. The thin passivating layer will be at most a few hundred monolayers thick, and typically less than 100 monolayers thick, but advantageously less than 80, 60, 40, 20, 15, 10, 8, 6, 5, 4, 3, or 2 monolayers average thickness. Next, the second material is deposited on the thin passivating layer.

Equivalently, the invention may be used to passivate a surface of a III-V compound semiconductor by reversing the order of the processing, such that the thin passivating layer is deposited on the second material, followed by the growth of the first material on top of the thin passivating layer.

In a particular embodiment of the invention, the anion-rich III-V compound semiconductor is achieved by LTG molecular beam epitaxy (LTG-MBE) (e.g. U.S. Pat. No. 4,952,527 by Calawa et al., “Method of making buffer layers for III-V devices using solid phase epitaxy,” Aug. 28, 1990), where low substrate temperature (generally below 400° C.) favors excess anion incorporation in the thin passivating layer. An important anion-rich III-V compound semiconductor is LTG-GaAs, such that growth conditions are chosen to achieve 0.001-10% excess As, and the thickness of the thin passivating layer is less than 25 nm. Other illustrative embodiments of other low LTG materials include LTG-AlGaAs, LTG-InGaAs, LTG-InAlAs, LTG-InGaAlAs, LTG-GaP, LTG-InP, LTG-GaInP. Other LTG materials can similarly incorporate 0.001-10% excess anions in accordance with the invention.

The thin passivating layer can advantageously be annealed in order to grade its interface with the first or second materials, to grade the structure's dopant profile, to reduce the density of crystallographic defects, to reduce the density of trap states, or to attain other well-known benefits of thermal annealing. Annealing is most commonly accomplished by means of rapid thermal annealing (RTA), hot-gas annealing, or isothermal annealing though many other annealing techniques are suitable and well-known. Annealing can be carried out prior to, during, and/or after deposition of the second material.

It is well-known that certain anion-rich materials can be used to prevent surface Fermi level pinning in certain metal-semiconductor contacts. (See, for instance, S Lodha, D B Janes, N-P Chen, “Fermi level-unpinning in ex situ Schottky contacts on n-GaAs capped with low-temperature-grown GaAs,” Appl. Phys. Letters, 80(23) pp. 4452-4454 (2002); S Lodha, D B Janes, N-P Chen, “Unpinned interface Fermi level in Schottky contacts to n-GaAs capped with low-temperature-grown GaAs; experiments and modeling using defect state distributions,” J. Appl. Physics, 93(5), pp. 2772-2779 (2003).) It is also well-known that some of these anion-rich semiconductors advantageously retard the formation of a native oxide on air-exposed surfaces, allowing removal from the vacuum chamber of an MBE and ex situ deposition of Schottky or ohmic metal-semiconductor contacts without significant interference from the native oxide. This imperviousness to air contrasts with the surfaces of most near-stoichiometric III-V compound semiconductors, which readily form surface oxides that pin the Fermi level and present an oxide barrier on the semiconductor surface. In the prior art, the imperviousness to air has been exploited as a substitute for vacuum-transport to allow ex situ handling of semiconductor wafers for the purpose of depositing metal-semiconductor contacts without interference from oxide barriers, but has not gone beyond that insight.

These specification and figures are meant to illustrate the invention, and are not meant to be restrict the invention to the embodiments so described. The key features of the invention may be summarized as follows:
1. The in situ deposition of a thin (<10 nm) non-stoichiometric layer with sufficient excess anion to achieve:
   i. A high density of mid gap trap levels that prevent oxidation of the surface upon exposure to air.
   ii. A fully compensated, highly insulating, low interface state density layer after annealing with a low density of mid gap trap levels. A low density of mid gap trap levels should provide a net sheet trap density (integrated across the entire layer) of less than 1×10¹². In some cases, compensation may be used to fill (or empty) the traps and render them electrically inactive.
      The preferred embodiment uses undoped LTG-GaAs. Alternative non-stoichiometric layers may also be used, including incorporating intentional n-type, p-type, or other dopants, LTG-AlGaAs, LTG-InAlAs, LTG-InGaAs, LTG-InAs, LTG-GaInP, LTG-GaP, and any non-stoichiometric material. The non-stoichiometric material must provide a low density of sheet trap states (including interface states) after annealing. The invention does not require LTG-MBE, rather it requires forming the non-stoichiometric material.
2. The deposition of a suitable gate insulator dielectric layer (ex situ or in situ). In the preferred embodiment the gate insulator is JVD deposited Si₃N₄, but a wide range of other gate insulators and other deposition techniques can be used in accordance with the invention.
3. Annealing of the layer structure to reduce the density of uncompensated trap levels in the passivation layer (including at the surfaces of the passivation layer) to below an acceptable value such as 1×10¹² cm⁻² or 1×10¹¹ cm⁻².
4. The inventors note that several features are advantageous but not required:
   p-type doping is advantageous, but not required, and certain embodiments may make use to undoped or n-type doped non stoichiometric materials. It is required that the non-stoichiometric material be compensated after anneal, such that any residual sheet charge density is less than 1×10¹² cm⁻³.
   It is advantageous that the non-stoichiometric material exhibit virtually no oxidation when exposed to air. However, this is not required, because some embodiments of the invention may use vacuum transfer of the epitaxial layer to the dielectric insulator deposition chamber, preventing any exposure to air.
   JVD of Si₃N₄ is advantageous, because JVD provides a very high quality dielectric insulator at low temperature, and only moderate temperature annealing is necessary to densify such layers. Alternative embodiments may use other dielectric materials and other deposition techniques provided such materials and deposition techniques provide a low fixed interface charge and a low trap density.
5. Certain aspects of the invention may be summarized as methods for passivating surface states at the interface between a first compound III-V semiconductor layer and a first dielectric insulator where the III-V compound semiconductor includes at least one group III element (In, Ga, Al) and one group V element (As, P, N, Sb), passivation is achieved by providing a thin, anion-rich III-V semiconductor layer between the first semiconductor and the first dielectric layer and sequencing the growth of the first and second layers to allow the thin intervening layer to be grown; such as where the thin, anion-rich III-V semiconductor semiconductor layer is LTG-GaAs; or where the LTG-GaAs is grown at a substrate temperature lower than 400° C.; or where the LTG-GaAs is doped with Be to a doping density between 1×10¹⁶ and 2×10²⁰ cm⁻³; or where the thickness of the LTG-GaAs is less than 10 nm; or where the thin, anion-rich semiconductor layer is any III-V compound semiconductor with at least 0.001% excess anion; or where the thin, anion-rich semiconductor layer comprises AlGaAs, InAlAs, InGaAs, InAlGaAs, GaP, InP, or GaInP; or where the thickness of the second semiconductor layer is below the pseudomorphic limit; or where the first dielectric layer is Si₃N₄ deposited by JVD; or where the first dielectric layer is SiO₂ deposited by CVD; or where the defect-density (including surface state density and fixed insulator charge density) is lowered by annealing.
6. Heavy p-type doping is not the preferred embodiment, because heavy p-type doping usually leads to short recombination lifetimes and high residual concentrations of excess As.
7. Light p-type doping can be advantageous. 1E18 doping at 2 nm thickness leads to a charge density of 2E11 cm⁻², which may be an acceptable interface charge density for some applications.
8. Undoped is sometimes superior to doped. Certain undoped layers (e.g. LTG-GaAs, LTG-InAlAs) will not oxidize in air, and undoped layers can often shed their excess As upon anneal without degradation, resulting in a layer that exhibits a very low density of deep level states (both “bulk” and interface).
9. Si₃N₄ is porous to As. Indeed annealing experiments of stoichiometric GaAs capped with As show a significant amount of diffusion of both Ga and As into Si₃N₄, with significantly higher concentrations of out-diffusing As. These annealing experiments also show that providing an external source of As (As pressure in the annealing chamber) can combat some of the loss of As through the Si₃N₄. Providing an internal source of excess As combats this loss and can promote annealing of the GaAs into a better crystalline quality.
10. A barrier is generally required between the surface passivation layer and the active channel region. This is particularly true when the channel region uses a lower band gap material than the surface passivation layer, but may also be true for a GaAs passivation layer on a GaAs channel.
   It is worth noting that, while we have described a general technique for passivating the surfaces of III-V compound semiconductors, there are certain limitations of the technique. For example, passivation layers that are thicker than the critical thickness for pseudomorphic growth may introduce defect levels associated with the MISFET and threading dislocations that may result in an unacceptably high density of defect states in the passivation layer. For lattice-mismatched layers that are pseudomorphic, but exhibit a high amount of strain, additional deep levels may be introduced by the strain. Certain combinations of materials may also promote diffusion of the excess anion or other defects into the active channel of the device during annealing, resulting in an excessive defect density that ruins performance. In some cases, the passivation layer may form a quantum well at the surface, which may act as a parasitic conduction channel, as well as a carrier trapping channel, lowering performance. Additionally, not all layers containing excess anion will necessarily be useful passivation layers—some such layers may not provide a reduced interface state density upon anneal.

The invention therefore uses thin passivation layers such as LTG-GaAs (and LTG-AlGaAs, LTG-InGaAs, LTG-InAlAs, and others), may optionally require a barrier layer between the passivation layer and the channel, requires the deposition of a suitable dielectric that does not introduce a significant additional surface or dielectric states, and requires annealing (either prior, during, or after deposition of the dielectric) to lower the defect density in the passivation layer and at the surface of the passivation layer. The defect density is reduced by redistribution of the excess anion, generally through desorption of the excess anion such that it exits the passivation layer, and diffuses into the dielectric layer (where it may become inactive) or through the dielectric layer (where it is removed entirely from the insulator-semiconductor system). Some of the excess anion may remain in the passivation layer or dielectric layer, provided that its density is low enough to keep the interface state density (including interface states, fixed charge, and mobile charge) below 1×10¹² cm⁻³ (optionally below 1×10¹⁰ cm⁻³, and optionally below 1×10¹⁰ cm⁻³), or provide it is compensated by an opposite type of defect level such that the net charge is below 1×10¹² cm⁻³ (optionally below 1×10¹⁰ cm⁻³, and optionally below 1×10¹⁰ cm⁻³) under the normal operational conditions of the device.

### BRIEF DESCRIPTION OF THE DRAWINGS

FIG. 1A shows a prior art interface between n-type GaAs and SiO₂. FIG. 1B shows the band diagram of the interface of FIG. 1A. FIG. 1C shows a prior art interface between p-type GaAs and SiO₂. FIG. 1D shows the band diagram of the interface of FIG. 1C.

FIG. 2A shows a prior art MOS layer structure. FIG. 2B shows the band diagram of FIG. 2A with an applied bias to achieve zero electrical field in the insulator. FIG. 2C shows the band diagram of FIG. 2A under reverse-bias conditions. FIG. 2D shows the band diagram of FIG. 2A under forward bias conditions.

FIG. 3A shows a prior art MES layer structure. FIG. 3B shows the band diagram of FIG. 3A under zero bias conditions. FIG. 3C shows the band diagram of FIG. 3A under reverse-bias conditions. FIG. 3D shows the band diagram of FIG. 3A under forward bias conditions.

FIG. 4A shows the preferred embodiment of the invention. FIG. 4B shows a MISFET produced using the invention that is capable of achieving inversion of the channel.

FIG. 5A shows the layer structure in accordance with the invention. FIG. 5B shows how a MIS diode can be fabricated from the layer structure shown in FIG. 5A.

FIG. 6A shows the experimental capacitance-voltage of a MIS diode in accordance with the invention prior to annealing. FIG. 6B shows the experimental capacitance-voltage of a MIS diode in accordance with the invention after annealing to 400° C. for 1 min. FIG. 6C shows the experimental capacitance-voltage of a MIS diode in accordance with the invention after annealing to 500° C. for 1 min. FIG. 6D shows the experimental capacitance-voltage of a MIS diode in accordance with the invention after annealing to 600° C. for 1 min.

FIG. 7A shows the current-voltage of a MIS diode fabricated in accordance with the invention after annealing to 500° C. for 1 min. FIG. 7B shows the current-field characteristics of a MIS diode fabricated in accordance with the invention after annealing to 500° C. for 1 min.

FIG. 8A shows an alternative embodiment of the invention suitable for passivating an InP surface. FIG. 8B show an alternative embodiment of the invention for passivating an InAs surface. FIG. 8C shows an alternative embodiment of the invention for passivating an InGaAs surface. FIG. 8D shows a MISFET structure fabricated from the alternative embodiments shown in FIG. 8C.

FIG. 9A shows the layer structure of an alternative embodiment useful for CCD applications. FIG. 9B shows a CCD structure fabricated from the layer structure shown in FIG. 9A.

### DETAILED DESCRIPTION OF THE FIGURES

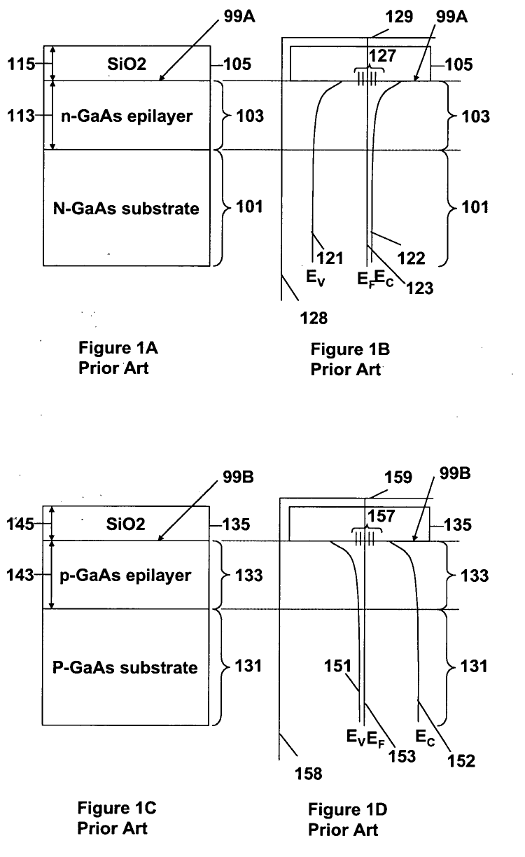

Reference is now made to FIG. 1A, showing a prior art attempt to passivate an n-type GaAs surface 99A by depositing layer 105 of SiO₂ to a thickness 115. An n-type GaAs epilayer 103 is grown on top of an n-type GaAs substrate 101 to a thickness 113. Next, SiO₂ layer 105 is deposited by any method, including PECVD, JVD, or any other suitable deposition technique.

Reference is now made to FIG. 1B, showing the band diagram of the layer structure of FIG. 1A. The potential energy 129 is plotted as a function of depth 128, showing the conduction band edge 122, the Fermi level 123, and the valence band edge 121. The break in crystal symmetry at interface 99A, results in incomplete, frustrated, or dangling bonds that act as surface states 127, typical with energy levels inside the forbidden band gap, acting as deep level surface traps and surface generation sites. The surface state density for GaAs and other III-V compound semiconductors is typically large enough to cause significant band bending near the surface 99A as shown in FIG. 1B. This band bending promotes minority carrier recombination, resulting in a loss mechanism for bipolar devices such as LEDs, solar cells, and HBTs.

Reference is now made to FIG. 1C, showing a prior art attempt to passivate a p-type GaAs surface 99B by depositing dielectric layer 135 of Si₃N₄ to a thickness 145. A p-type GaAs epilayer 133 is grown on a p-type GaAs substrate 131 to a thickness 143. Next, Si₃N₄ layer 135 is deposited by any method, including PECVD, JVD, or any other suitable deposition technique.

Reference is now made to FIG. 1D, showing the band diagram of the layer structure of FIG. 1C. The potential-energy 159 is plotted as a function of depth 158, showing the conduction band edge 152, the Fermi level 153, and the valence band edge 151. The break in crystal symmetry at interface 99B, results in incomplete, frustrated, or dangling bonds that act as surface states 157, typical with energy levels inside the forbidden band gap, acting as deep level surface traps and generation sites. The surface state density for GaAs and other III-V compound semiconductors is typically large enough to cause significant band bending near the surface 99B as shown in FIG. 1D. This band bending promotes minority carrier recombination, resulting in a loss mechanism for bipolar devices such as LEDs, solar cells, and HBTs.

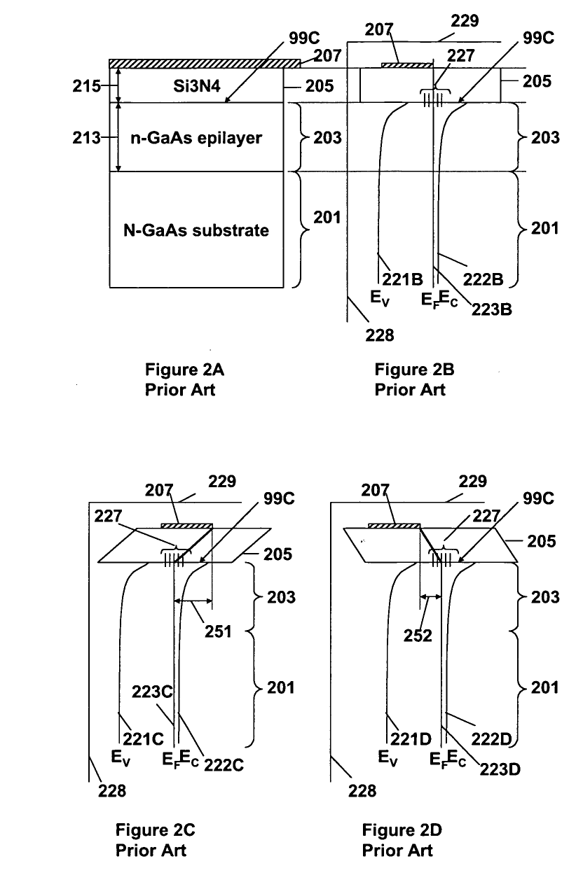

Reference is now made to FIG. 2A, showing a prior art attempt to create a MOS device. An n-type GaAs epilayer 203 is grown on an n-type GaAs substrate 201 to a thickness 213. Next, Si₃N₄ layer 205 is deposited to a thickness 215 using any suitable method. The interface between layers 203 and 205 is 99C. Finally, metal 207 is deposited on layer 205, where the metal is any suitable high conductivity material, including Al, Au, Ti, Ni, Pt, and Cu.

Reference is now made to FIG. 2B, showing the band diagram of the MIS structure of FIG. 2A under bias conditions suitable to achieve approximately zero electrical field in the insulator layer. The potential energy 229 is plotted as a function of depth 228, showing the conduction band edge 222B, the Fermi level 223B, and the valence band edge 221B. The break in crystal symmetry at interface 99C, results in incomplete, frustrated, or dangling bonds that cause surface states 227 to occur. To achieve a zero electrical field across oxide 205 generally requires the application of a voltage between the metal 207 and the bulk semiconductor (through an ohmic contact to 201). In general this bias is not zero, because the Fermi level (relative to vacuum) at surface 99C is different from the Fermi level at metal 207, provided that insulator 205 does not conduct charge between metal 207 and surface 99C.

Reference is now made to FIG. 2C, showing the band diagram of the MIS structure of FIG. 2A under strong reverse-bias conditions. The potential energy 229 is plotted as a function of depth 228, showing the conduction band edge 222C, the semiconductor Fermi level 223C, and the valence band edge 221C. A voltage produces a separation 251 of the metal 207 Fermi level from the bulk Fermi level. Under this reverse-bias condition, the Fermi level of the metal 207 has a larger (more positive) value than the Fermi level at the surface 99C. If surface states 227 were not present, this reverse-bias would cause an electrical field to penetrate into layer 203, increasing the width of the depletion region. However, for most III-V semiconductors, surface states 227 are sufficient to screen the applied electrical field, resulting in little or no penetration of the electrical field into the layer 203, and instead dropping substantially all of the applied electrical field across insulator layer 205.

Reference is now made to FIG. 2D, showing the band diagram of the MIS structure of FIG. 2A under strong forward bias conditions. The potential energy 229 is plotted as a function of depth 228, showing the conduction band edge 222D, the semiconductor Fermi level 223D, and the valence band edge 221D. A voltage produces a separation 252 of the metal Fermi level from the bulk Fermi level. Under this forward bias condition, the Fermi level of the metal 207 has a smaller (less positive) value than the Fermi level at the surface 99C. If surface states 227 were not present, this forward bias would cause an electrical field to penetrate into layer 203, reducing the width of the depletion width. However, for most III-V semiconductors, surface states 227 are sufficient to screen the applied electrical field, resulting in little or no penetration of the electrical field into the layer 203, and instead dropping substantially all of the applied electrical field across layer 205.

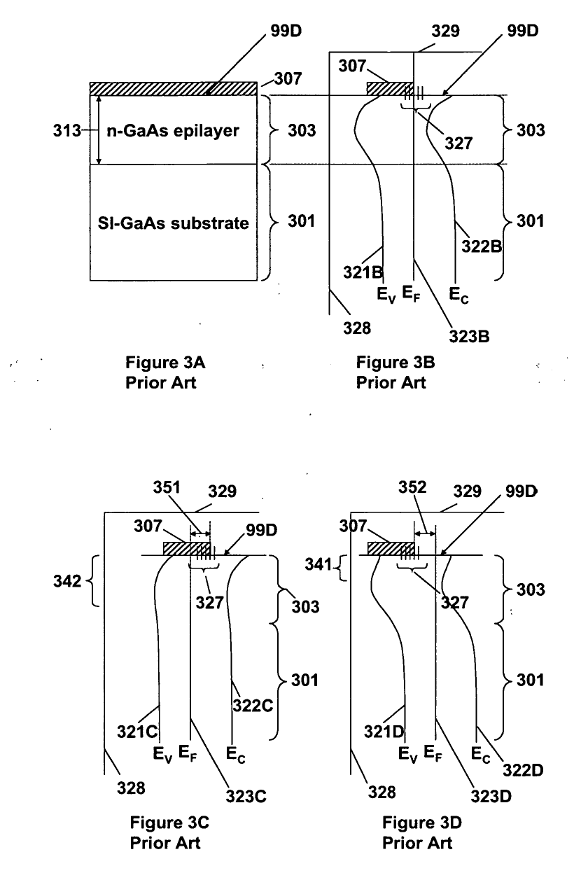

Reference is now made to FIG. 3A showing a prior art solution to the MIS problem illustrated by FIGS. 2A, 2B, 2C and 2D. By eliminating the dielectric insulator layer and forming a metal contact directly to the semiconductor, a Schottky diode is formed in place of the MIS diode of the previous figures. On top of a semi-insulating GaAs substrate 301 is grown an n-type GaAs epilayer 303 to a thickness 313. Directly on top of layer 303 is deposited a metal layer 307, with interface 99D between layers 307 and 303.

Reference is now made to FIG. 3B, showing the band diagram of the Schottky diode structure of FIG. 3A under zero bias conditions. The potential energy 329 is plotted as a function of depth 328, showing the conduction band edge 322B, the Fermi level 323B, and the valence band edge 321B. The disruption of crystal symmetry at interface 99D, results in incomplete, frustrated, or dangling bonds that cause surface states 327 to occur. Note that since the metal 307 is in intimate contact with the semiconductor layer 303 at interface 99D, the Fermi level of metal 307 lines up with the Fermi level in the semiconductor 303 at surface 99D, through the transfer of charge between the metal and the semiconductor, resulting in a built-in voltage. In the case of most III-V semiconductors, the surface states pin the Fermi level at the semiconductor surface, making the built-in voltage insensitive to the metal work function or to the details of the doping of semiconductor layer 303.

Reference is now made to FIG. 3C, showing the band diagram of the Schottky diode structure of FIG. 3A under strong reverse-bias conditions. The potential energy 329 is plotted as a function of depth 328, showing the conduction band edge 322C, the semiconductor Fermi level 323C, and the valence band edge 321C. A voltage produces a separation 351 of the metal Fermi level from the bulk Fermi level. Under this reverse-bias condition, the Fermi level of the metal 307 has a larger (more positive) value than the Fermi level in the bulk of semiconductor layer 303. Since the metal 307 is in intimate contact with surface 99D and surface states 327, it can readily move the surface Fermi level with respect to the Fermi level in the bulk of layer 303, causing an electrical field to penetrate into layer 303, increasing the width of depletion region 342.

Reference is now made to FIG. 3D, showing the band diagram of the MIS structure of FIG. 3A under strong forward bias conditions. The potential energy 329 is plotted as a function of depth 328, showing the conduction band edge 322D, the semiconductor Fermi level 323D, and the valence band edge 321D. A voltage produces a separation 352 of the metal Fermi level from the bulk Fermi level. Under this forward bias condition, the Fermi level of the metal 307 has a smaller (less positive) value than the Fermi level in the bulk of layer 303. Since the metal 307 is in intimate contact with the surface 99D and surface states 327, it can readily move the surface Fermi level with respect to the Fermi level in the bulk of layer 303, causing an electrical field to penetrate into layer 303, reducing the width of the depletion region 341 and causing an accumulation of electrons to occur.

Therefore, the Schottky diode overcomes the problems of the MIS structure and allows the surface Fermi level to be modulated. However, because metal 307 is in intimate contact with semiconductor 303, minority carrier recombination at surface 99D is high, eliminating the possibility of forming an inversion charge layer at the surface. Furthermore, the intimate contact between metal 307 and semiconductor 303 enhances current flow between metal 307 and semiconductor 303, which is often detrimental to device performance. This is particularly true of forward bias conditions, where large currents readily flow, making it difficult to achieve a large accumulation of charge at or near the surface 99D.

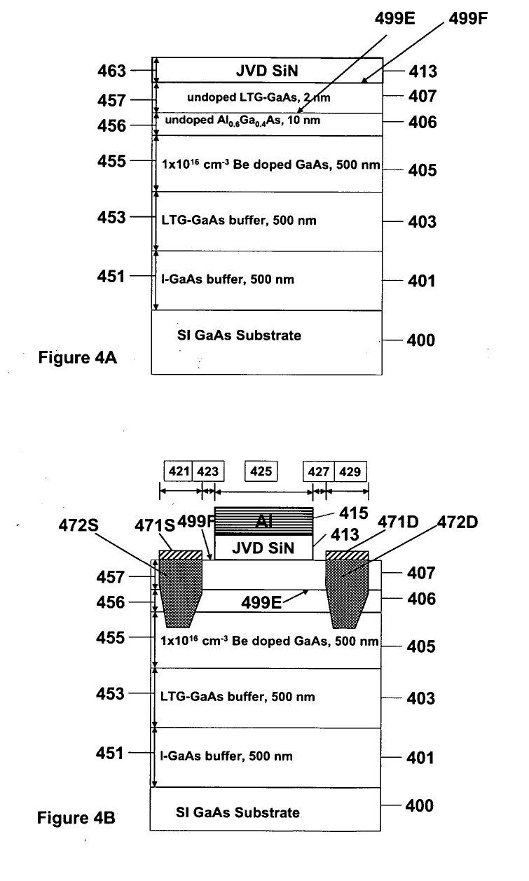

Reference is now made to FIG. 4A, showing a layer structure of the preferred embodiment of the present invention. Molecular beam epitaxy (MBE) is used to grow layers 401, 403, 405, and 407 epitaxially on a semi-insulating GaAs substrate 400. First, an undoped GaAs layer 401 is grown to a thickness 451 of 500 nm to provide an initial buffer layer and initiate high quality growth of the subsequent layers. Next, the substrate temperature is reduced to about 250° C. and a LTG-GaAs (LTG-GaAs) buffer layer 403 is grown to a thickness 453 of 500 nm. After annealing, the LTG layer 403 provides a highly insulating buffer layer that isolates the substrate 400 and buffer layer 401 from the active regions of the device. On top of layer 403 is grown the layer 405 which is the active layer of the device. Layer 405 is grown using normal growth temperatures to a thickness 455 of 500 nm using a beryllium (Be) doping density of about 1×10¹⁶ cm⁻³. Next, Al_{0.4}Ga_{0.6}As barrier layer 406 is grown to a thickness 456 of 10 nm to provide a barrier between the active layer 405 and the surface passivation layer 407. Next, the growth is interrupted and the substrate temperature is rapidly lowered to 250° C. for the deposition of the i-GaAs surface passivation layer 407 to a thickness 457 of 2 nm. Surface 499E is the interface between layers 406 and 407, while surface 499F is the top surface which will be exposed to air upon unloading from the MBE. Growth of GaAs using MBE at substrate temperatures below 400° C. is generally called LTG, and is characterized by the incorporation of a significant fraction of excess As in the epilayer (generally larger than 0.001-10% excess As) (see, e.g. M R Melloch, J M Woodall, E S Harmon, N Otsuka, F H Pollak, D D Nolte, R M Feenstra and M A Lutz, “Low-temperature Grown III-V materials, Annual Reviews of Materials Science, 25, pp. 547-600 (1995)). The use of LTG prevents oxidation of the surface 499F when exposed to air, reducing the formation of interface states due to the native oxide of GaAs (e.g. S Lodha, D B Janes, N-P Chen, “Fermi level unpinning in ex situ Schottky contacts on n-GaAs capped with low-temperature-grown GaAs,” Appl. Phys. Letters, 80(23) pp. 4452-4454 (2002); S Lodha, D B Janes, N-P Chen, “Unpinned interface Fermi level in Schottky contacts to n-GaAs capped with low-temperature-grown GaAs; experiments and modeling using defect state distributions,” J. Appl. Phys., 93(5), pp. 2772-2779 (2003)). Oxidation of GaAs surfaces generally requires the presence of holes at the surface, which, for n-type, lightly doped, or intrinsic layers are normally provide by photogeneration in the presence of light (even room light). However, LTG-GaAs exhibits minority carrier lifetimes on the order of 1 ps, which is at three orders of magnitude smaller than the minority carrier lifetime of high-quality normal temperature growth GaAs, which greatly retards the oxidation of the GaAs surface. (see. E H Chen, D T McInturff, T P Chin, M R Melloch, and J M Woodall, “Use of annealed LTG-GaAs as a selective photoetch-stop layer,” Appl. Phys. Lett., 58, p. 1678-1680, (1996)). It is well-known that LTG-GaAs is usually n-type as-grown. In bulk films of LTG-GaAs, the excess As incorporated due to the LTG will precipitate into metallic As clusters after annealing. However, the use of a thin film of LTG-GaAs in close proximity to the surface 499F provides another means of removing the excess As. The excess As can diffuse to surface 499F, where it can exit the crystal. Additionally, Al_{0.4}Ga_{0.6}As layer 406 provides a barrier layer that blocks the excess As from diffusing to the active layer 405 of the device. This so-called thin anion-rich layer will advantageously be less than 10 nm thick, and even more advantageously less than 5 nm, 3 nm, 2 nm, or 1 nm thick.

The structure consisting of substrate 400, and layers 401, 403, 405, 406, and 407 may now be removed from the MBE, exposed to atmosphere, and transferred to the JVD chamber. JVD is then used to deposit a dielectric Si₃N₄ layer 413 to a thickness 463 of 10 nm on top of surface passivation layer 407. (T P Ma, “Making Silicon Nitride Film a Viable Gate Dielectric,” IEEE Trans. Electron. Dev., 45, p. 680 (1998).) JVD is particularly advantageous because it achieves deposition of high quality Si₃N₄ despite a low substrate temperature during growth. Furthermore, JVD limits the exposure of surface 499E to a plasma, so avoids damage to the GaAs layer 407.

After JVD deposition of the nitride layer, the wafer consisting of substrate 400 and layers 401, 403, 405, 406, 407, and 413 must be annealed. The annealing step drives the majority of the excess As out of layer 407, reducing its defect density. By reducing the density of electrically excess As to below 1×10¹⁸ cm⁻³, the effective sheet trapping density can be reduced below 2×10¹¹ cm⁻², which is acceptable for many MIS applications. In the preferred embodiment, the annealing step is 600° C. for 5 minutes, but those skilled in the art will recognize that other annealing procedures using different annealing times and temperatures, as well as multiple step annealing at multiple temperatures in accordance with the invention.

Due to the fact that layer 407 contains excess As, annealing this layer to high temperatures can be used to repair surface damage caused by deposition of the nitride, by providing a high excess As overpressure throughout layer 407 that promotes redistribution of the crystal atoms (Ga and As, as well as the Be dopant atoms to their correct sites (i.e. substitutional sites rather than anti-sites, precipitates, or interstitially.) (See U.S. Pat. App. No. 20030121468.) In addition, As is known to diffuse into and through dielectric films (including Si₃N₄) on top of GaAs. (See T Haga, N Tachino, Y Abe, J Kasahara, A Okubora, and H Hasegawa, “Out-diffusion of Ga and As atoms into dielectric films in SiOₓ/GaAs and SiN_{y}/GaAs systems,” J. Appl. Phys. 66, p. 5809-5815 (1989).) For the case of Si₃N₄ films on GaAs, the out-diffusion of As occurs at a faster rate than the out diffusion of Ga, which would normally result in a deficit of As in layer 407. However, due to the intentional introduction of excess As into layer 407, this excessive out-diffusion of As during anneal actually improves the stoichiometry of layer 407, and hence improves the crystalline quality of layer 407. Note that the As out diffusion through layer 413 is a complex function of annealing temperature profile, annealing time, Si₃N₄ layer 413 thickness and Si₃N₄ density. Optimizations—including optimization of the initial excess As in layer 407, of the thickness of layers 407 and 413, of the deposition parameters of layer 413, including the substrate temperature during deposition, of the density of layer 413, and of the annealing profile—can be used to reduce the total interface state density, which includes contributions from surface states and “bulk” states such as As anti-sites in layer 407.

It is well-known that annealing layer 413 is generally required to harden the Si₃N₄ and lower its interface and fixed charge densities, so the annealing optimizations must also simultaneously improve the dielectric properties of layer 413.

Pre-annealing of layer 407 prior to the JVD deposition of the nitride is also anticipated. In particular, the structure may be annealed prior to the JVD step to provide an additional means of controlling the amount of excess As in layer 407. Annealing may also be performed during the JVD deposition step by heating the substrate during depositon.

Reference is now made to FIG. 4B, showing how MISFET capable of achieving inversion in the channel can be made using from the layer structure shown in FIG. 4A. On top of the JVD Si₃N₄ layer 413 is deposited an aluminum gate metal layer 415 using conventional evaporation techniques. Photolithography is used to pattern gate metal layer 415 to a gate width 425 as shown in the figure. Post-metalization annealing can be used to improve the properties of the gate metal and reduce the interface and fixed charge density in the insulator, of the MIS structure consisting of the M (metal) layer 415, I (insulator) layer 413, and the underlying S (semiconductor) active layers, consisting of layers 405, 406, and 407. Preferably, this post-metalization anneal should raise the temperature to 400° C. for 30 min in forming gas. Next, source contact 471S and drain contact 471D are deposited and patterned using conventional lithographic techniques. The width of source contact 471S is 421, and the spacing between the source contact 471S and the gate is 423. The width of drain contact 471D is 429, and the spacing between the drain contact 471D and the gate is 427. Preferably, source contact 471S and drain contact 471D use an AuGeNi metalization, such that upon annealing, the contacts alloy with the underlying GaAs layers and form an ohmic n-type contact to the channel region of the device in layer 405. Region 472S and 472D are the alloyed contact regions where the AuGeNi contact has diffused into the underlying layers. Note that the annealing for the source/drain contacts can be combined with the post-metalization anneal of the gate insulator. The transistor can now be operated as a standard FET transistor with source 471S, gate 415, drain 471D. An optional body contact (not shown) can be made to layer 405 using AuZn metalization to form an ohmic p-type contact to this layer.

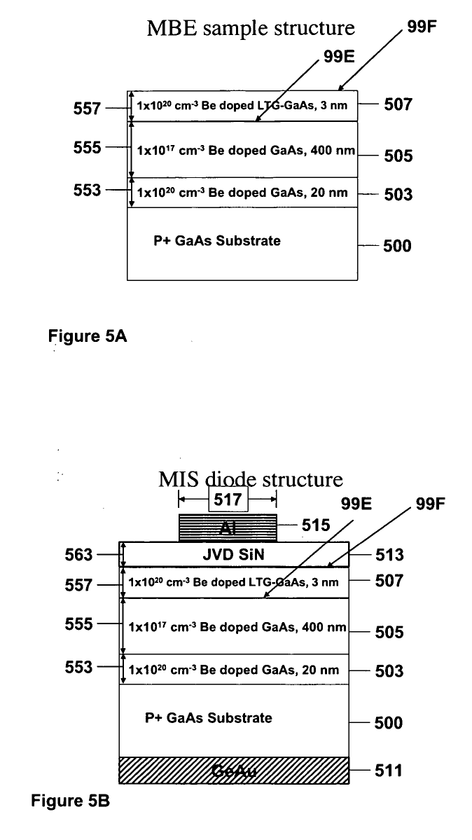

Reference is now made to FIG. 5A, showing a layer structure in accordance with the invention. MBE is used to epitaxially grow layers 503, 505, and 507 on a p-type GaAs substrate 500. First, a heavily doped p-type GaAs layer 503 is grown to a thickness 553 of 20 nm. The p-type dopant is Be and the doping density is 1×10²⁰ cm⁻³. Next, a lightly doped p-type GaAs layer 505 is grown to a thickness 555 of 400 nm using a Be doping density of about 1×10¹⁷ cm⁻³. Preferably, layer 503 is grown using hyperdoping and layer 505 is grown using conventional MBE techniques chosen to achieve the high quality material, where high materials quality means high mobility and long recombination/generation lifetimes. Next, the growth is interrupted and the substrate temperature is lowered to 225° C. for the deposition of p-type GaAs layer 507 to a thickness 557 of 3 nm using a Be doping density of 1×10²⁰ cm⁻³. Surface 99E is the interface between layers 505 and 507, while surface 99F is the top (exposed) surface of the growth. The p-type doping of the LTG-GaAs provides a means t& reduce the precipitation of excess As and a means for compensating some of the As anti-sites. (See N Atique, E S Harmon, J C P Chang, J M Woodall, M R Melloch, and N Otsuka, “Electrical and structural properties of Be- and Si-doped LTG-GaAs,” J. Appl. Phys., 77, pp. 1471-1476 (1995).) Layer 507 prevents the oxidation of surface 99F when exposed to air. We note here that as grown, LTG-GaAs is almost always n-type, even when doped with up to 1×10²⁰ cm⁻³ Be, which advantageously reduces oxidation in air because oxidation requires holes, which are minority carriers in n-type material, and the excess As incorporated during LTG results in very short recombination lifetimes, greatly reducing the presence of minority holes at surface 99F. However, upon high temperature annealing, Be-doped LTG-GaAs will convert to p-type because the density of the compensating, n-type excess As related point defects is reduced. In bulk films of LTG-GaAs, the excess As forms precipitates. However, in the invention, the use of a thin film of LTG-GaAs and the presence of surface 99F provides another means of removing the excess As. The excess As can diffuse to surface 99F, where it can exit the crystal. Note that p-type GaAs tends to promote diffusion of the excess As, which may result in lower excess As after anneal in p-type material. Also note that p-type doping of layer 507 is advantageous but not strictly required for the invention. Alternative embodiments of the invention may be undoped or even doped n-type.

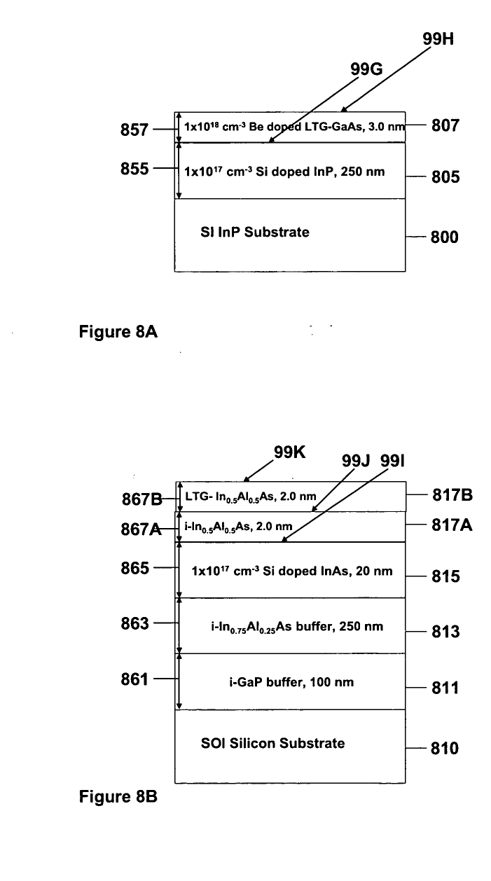

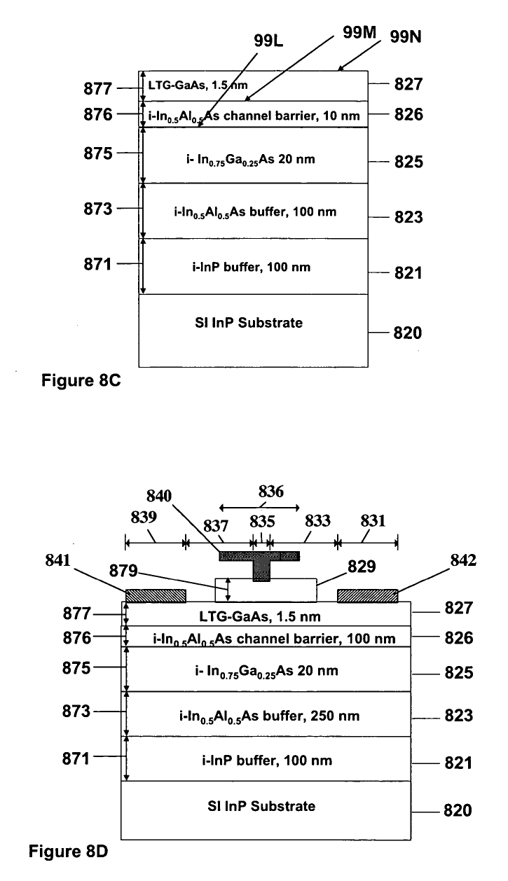

Excess As does not normally diffuse from a LTG layer to normal temperature growth layer because the diffusion mechanism is assisted by the presence of As anti-sites and Ga vacancies. In normal temperature growth GaAs, As anti-site densities and Ga vacancy densities are very low, greatly slowing the diffusion of the excess As in layer 505. Therefore we expect layer 505 to be virtually free of excess As. However, under some growth conditions and anneal conditions, it is feasible that a small fraction of the excess As would diffuse into layer 505, where it would act as an efficient recombination center. In such cases, it would be advantageous to insert a barrier layer between layers 505 and 507 to prevent such As diffusion. For example, AlGaAs has been shown to be an excellent barrier layer in LTG-GaAs studies, so a thin layer of AlGaAs inserted between layers 505 and 507 could be used to advantageously prevent As migration into the active layer of the device. Such barrier layers will be particularly important for devices which incorporate lower band gap active layers since migration of excess anion may be enhanced in lower band gap layers where the formation energies for antisites and vacancies is lower, so it would be advantageous to incorporate a wider band gap barrier layer in such structures (see FIG. 8C below).

While the invention is taught using in situ deposition of the anion rich passivation layer, the inventors anticipate using ex situ deposition of the anion-rich passivation layer, which will be useful for passivation of surfaces that are exposed during processing. As noted above, merely 5% coverage by an oxygen monolayer is sufficient to pin the Fermi level, so successful ex situ techniques must remove or prevent contamination by oxygen (or water, hydroxyl, and other sources of oxygen). Well-known techniques for doing this include wet chemical oxide removal (such as with ammonia hydroxide) followed by immediate introduction into vacuum (for deposition of the anion rich layer) without appreciable exposure to oxygen, high temperature oxide desorption in vacuum, gettering of surface oxygen and rendering the surface oxygen inactive, among others. Gettering and/or inactivation of surface oxygen can be accomplished during the deposition of the anion-rich passivation layer itself, where the excess anion is used to getter or compensate the surface oxygen.

Reference is now made to FIG. 5B, showing how a MIS capacitor can be fabricated from the layer structure shown in FIG. 5A. First, JVD is used to deposit a Si₃N₄ layer 513 to a thickness 563 of 10 nm. After JVD deposition of the nitride, the wafer consisting of substrate 500, and layers 503, 505, 507, and 513 must be annealed. The annealing step drives the majority of the excess As out of layer 507, reducing the defect-density of this layer. By reducing the density of electrically excess As to below 1×10¹⁸ cm⁻³, the effective sheet trapping density is less than 3×10¹¹ cm⁻², which is acceptable for many MIS applications. In the preferred embodiment, the annealing step is 600° C. for 5 minutes, but those skilled in the art will recognize that other annealing procedures using different annealing times and temperatures, as well as multiple step annealing at multiple temperatures is in accordance with the invention.

Due to the fact that layer 507 contains excess As, annealing this layer to high temperatures can be used to repair surface damage caused by deposition of the nitride by providing a high excess As overpressure that promotes redistribution of the crystal atoms (Ga and As, as well as the Be dopant atoms, disclosed in U.S. Pat. App. No. 20030121468) to their correct sites. The annealing also provides a means for reducing the excess As concentration in layer 507 via diffusion of the excess As out of layer 507 through surface 99F, into and through layer 513, where it may be removed into the ambient of the annealing chamber. Annealing of layer 513 is generally required to harden the Si₃N₄ layer and lower the interface and fixed charge density of the layer, so the annealing optimizations should also be arranged to harden layer 513 simultaneously.

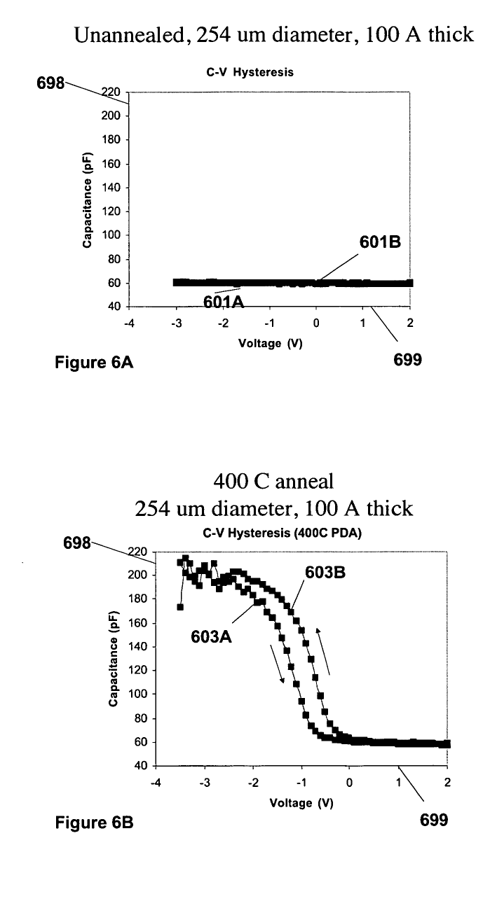

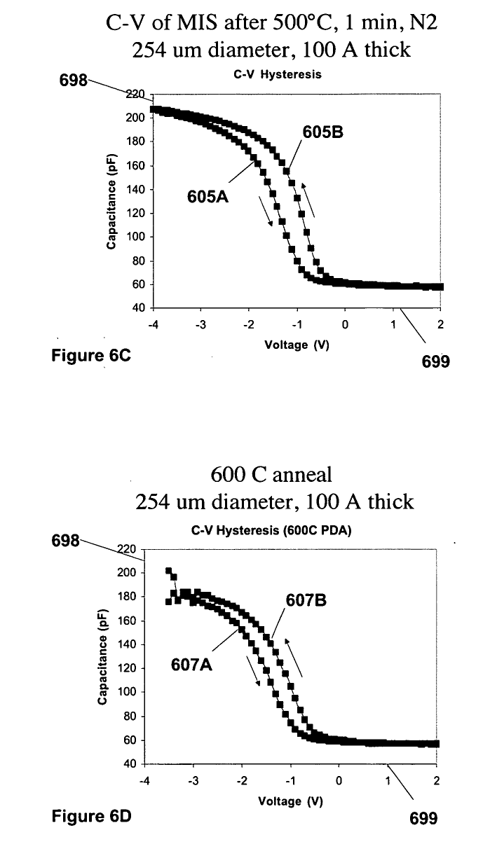

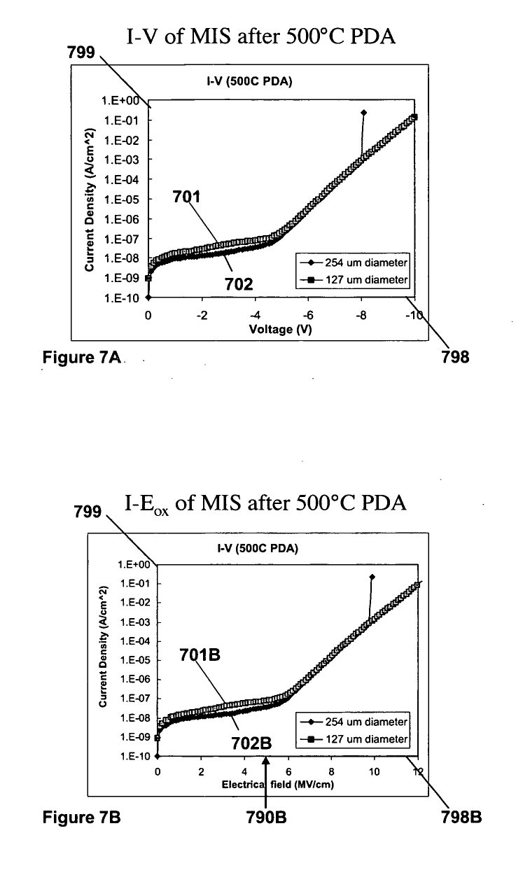

Next, dot contacts 515 are deposited using aluminum deposition through a shadow mask. The diameter 517 of the MIS dot contact is 254 μm for the experimental measurements presented in FIGS. 6A, 6B, 6C and 6D (below). In FIGS. 7A and 7B, the diameter 517 is 254 μm or 127 μm as indicated in the figure. Contact to the p-type GaAs substrate are made using a large area AuGe contact 511 to the back side of substrate 500, forming an ohmic contact.

Reference is now made to FIG. 6A, showing a plot of the capacitance (plotted on axis 698) as a function of the bias voltage (plotted on axis 699) for the MIS structure shown in FIG. 5B, prior to any annealing. Curve 601A is the curve for this sample when sweeping the voltage from negative-to-positive, and curve 601B is the curve for this sample when sweeping the voltage from positive to negative. Since the two curves are nearly identical, it is difficult to distinguish the two curves.

Reference is now made to FIG. 6B, showing a plot of the capacitance (plotted on axis 698) as a function of the bias voltage (plotted on axis 699) for the MIS structure shown in FIG. 5B, after annealing to 400° C. for 60 seconds. Curve 603A is the curve for this sample when sweeping the voltage from negative to positive, and curve 603B is the curve for this sample when sweeping the voltage from positive to negative. A hysteresis is now observed in the two curves, with curve 603A being shifted slightly by approximately −0.5 V with respect to curve 603B. This hysteresis is indicative of surface states that store charge when swept in one direction, causing a flat band voltage shift. In addition, a fixed charge flat band voltage shift of about 1.5 V can be estimated from this measurement, which is indicative of a fixed charge density of about 1×10¹² cm⁻².

Reference is now made to FIG. 6C, showing a plot of the capacitance (plotted on axis 698) as a function of the bias voltage (plotted on axis 699) for the MIS structure shown in FIG. 5B, after annealing to 500° C. for 60 seconds. Curve 605A is the curve for this sample when sweeping the voltage from negative to positive, and curve 605B is the curve for this sample when sweeping the voltage from positive to negative. Similar flat band voltage shifts and hysteresis to those shown in FIG. 6B are observed.

Reference is now made to FIG. 6D, showing a plot of the capacitance (plotted on axis 698) as a function of the bias voltage (plotted on axis 699) for the MIS structure shown in FIG. 5B, after annealing to 600° C. for 60 seconds. Curve 607A is the curve for this sample when sweeping the voltage from negative to positive, and curve 607B is the curve for this sample when sweeping the voltage from positive to negative. Similar flat band voltage shifts and hysteresis to those shown in FIGS. 6B and 6C are observed.

We note here that FIGS. 6B, 6C and 6D show a clear accumulation characteristic (for voltages more negative than about −2V) and a clear depletion characteristic (for voltages more positive than about −1 V). Such characteristics are indicative of a relatively high quality MIS diode. FIG. 6A, on the other hand, shows a relatively flat capacitance characteristic, with the capacitance value being similar to that of the depletion characteristic of FIGS. 6B, 6C and 6D. This indicates that the fixed charge density of the MIS diode in FIG. 6A is sufficiently large to shift the flat band voltage to a value more negative than about −4V, indicating a larger fixed charge density in the unannealed sample. Annealing to temperatures larger than 400° C. for 60 seconds is sufficient to move the flat band voltage closer to the zero volts, resulting in more nearly ideal MIS characteristics.

Reference is now made to FIG. 7A, showing a plot of the current density (on axis 799) as a function of the bias voltage (on axis 798). Curve 701 is for a MIS diode with a diameter 517 of 127 μm and Curve 702 is for a MIS diode with a diameter 517 of 254 μm. The curve shows a current below 0.1 μA/cm² for voltages between 0V and −4V, and then an exponential increase in current for voltages between −5V and −10V. This exponential increase occurs due to tunneling and breakdown in Si₃N₄ dielectric layer 513.

Reference is now made to FIG. 7B, showing a plot of the current density (on axis 799) as a function of the effective oxide electrical field (on axis 798B). Curve 701B is for a MIS diode with a diameter 517 of 127 μm and Curve 702B is for a MIS diode with a diameter 517 of 254 μm. The curve shows a current below 0.1 μA/cm² for electrical field magnitudes smaller than 5 MV/cm, and then an exponential increase current for electrical field magnitudes greater than 6 MV/cm. Point 790B indicates an electrical field magnitude of 5 MV/cm on axis 798B. These curves indicate that the particular embodiment of the invention is capable of producing a MIS structure capable of withstanding an electrical field in the dielectric of about 5 MV/cm without breaking down.

Reference is now made to FIG. 8A showing an alternative embodiment of the invention suitable for MIS devices such as MISFETs when the semiconductor region is InP. A InP layer 805 is deposited on a semi-insulating InP substrate 800 to a thickness 855 of 250 nm using conventional MBE growth techniques. Next, growth is interrupted and the substrate temperature is lowered to 300° C. for the deposition of the LTG-GaAs layer 807 to a thickness 857 of 3.0 nm doped with Be to a doping density of about 1×10¹⁸ cm⁻³. Due to the use of a higher growth temperature, less excess As is incorporated during growth, allowing a lower Be concentration to be used. This GaAs layer is thin enough to be made pseudomorphic, hence a low-defect, single-crystal passivation layer (see Y Wada, and K Wada, “Relaxation of GaAs surface band bending by atomic layer passivation,” J. Vac. Sci. Technology V 11, p. 1598-1602 (1993)). The interface between layers 805 and 807 is 99G. The top interface is 99H. The layer structure shown in FIG. 8A may now be removed from the MBE and exposed to air. Deposition of a high quality insulator dielectric is layer necessary to complete the structure, which can be done using any convenient technique that produces a high quality insulating dielectric at a temperature below 600° C. (where the GaAs would decompose). Suitable deposition techniques include using conventional CVD, PLD, JVD, LPD or evaporation techniques among others, as well as anodic or other oxidation of a deposited layer. If deposition of the insulating dielectric occurs at low temperature, it is preferable to subject the wafer to rapid thermal annealing at 500° C. for 60 seconds. Other annealing temperatures and time profiles are anticipated as well.

Reference is now made to FIG. 8B showing an alternative embodiment of the invention suitable for MIS devices such as MISFETs when the semiconductor region is InAs. A GaP layer 811 is deposited on a silicon-on-insulator (SOI) substrate 810 to a thickness 861 of 100 nm. (See K J Bachmann, U Rossow, N Sukidi, H Castleberry, and N Dietz, “Heteroepitaxy of GaP on Si(100)*,” J. Vac. Sci. Technol. B, 14(4) pp. 3019-3029 (1996).). Next, an undoped In_{0.75}Al_{0.25}As buffer layer 813 is grown to a thickness 863 of 250 nm. Next, an InAs channel region 815 is grown to a thickness 865 of 20 nm. Layers 813 and 815 are preferably deposited by MBE using growth conditions optimized to provide high quality material. Next, undoped In_{0.5}Al_{0.5}As layer 817A is grown to a thickness 867A of 2 nm. Layer 817A provides a barrier between the surface passivation layer 817B and the channel layer 815. Next, growth is interrupted and the substrate temperature is lowered to 300° C. for the deposition of the LTG of the undoped In_{0.5}Al_{0.5}As surface passivation layer 817B to a thickness 867B of 2.0 nm. The combined layers 817A and 817B are sufficiently thin to be pseudomorphic, hence a low-defect, single-crystal passivation layer. In analogy to LTG-GaAs and LTG-AlGaAs, LTG-In_{0.5}Al_{0.5}As also incorporates a significant fraction of excess As during growth. The interface between layers 815 and 817A is 99I. The interface between layers 817A and 817B is 99J. The top interface is 99K. The layer structure shown in FIG. 8B may now be removed from the MBE and exposed to air. Deposition of a high quality insulator dielectric is necessary to complete the structure, which can be done using any convenient technique that produces a high quality insulating dielectric at a temperature below 600° C. (where the GaAs would decompose). Suitable deposition techniques include using conventional CVD, PLD, JVD, liquid phase deposition (LPD) or evaporation techniques, as well as anodic oxidation of a deposited layer, or any other suitable deposition or oxidation technique. If deposition of the insulating dielectric occurs at low temperature, it is preferable to rapidly thermally anneal the structure to 500° C. for 60 seconds. Other annealing temperatures and time profiles are anticipated as well.

Reference is now made to FIG. 8C, showing an alternative embodiment of the invention. First, an undoped InP buffer layer 821 is grown on a semi-insulating InP substrate 820 to a thickness 871 of 100 nm. Next, an undoped InAlAs buffer layer 823 lattice-matched to the InP substrate 820 is grown on to a thickness 873 of 100 nm. Next, a pseudomorphic In_{0.75}Ga_{0.25}As channel layer 825 is grown to a thickness 875 of 20 nm. Next, an n-type In_{0.5}Al_{0.5}As channel barrier layer 826 is grown to a thickness 876 of 10 nm with a Si doping density of 1×10¹⁸ cm⁻³. During the growth of layer 826, the substrate temperature is ramped down as quickly as possible to achieve a growth temperature of 250 C at the interface 99M between layers 826 and 827. Without growth interruption, LTG-GaAs layer 827 is deposited to a thickness 877 of 1.5 nm. The interface between layers 825 and 826 is 99L. The interface between layers 826 and 827 is 99M. The top (exposed) interface is 99N.

Reference is now made to FIG. 8D, showing how the layer structure shown in FIG. 8C can be fabricated into a MISFET in accordance with the invention. A Si₃N₄ layer 829 is deposited by JVD on the LTG-GaAs passivation layer 827 to form the gate insulator of thickness 879 of 10 nm. The structure is annealed to 500° C. for 60 seconds. Standard photolithographic and etching procedures are used to define the area of the gate oxide 829, the T-gate structure 840, the source contact 841 and the drain contact 842. A gate metal 840 is deposited on the gate insulator 829 to achieve the T-gate structure as shown in FIG. 8D. The effective gate width is 835. The width of the T structure is 836. The active region of T-gate 840 is separated from the source contact 841 by a distance 837. The active region of T-gate 840 is separated from the drain contact 842 by a distance 833. The width of the source contact 841 is 839, and the width of the drain contact 842 is 831. Mesa isolation may be used to define the FET and isolate it from adjacent devices. In accordance with standard semiconductor device operation, the device shown in FIG. 8D may be operated as a depletion mode MISFET, by applying the appropriate voltages to the T-gate 840, the source contact 841, and the drain contact 842. The use of the invention greatly lowers the surface state densities, particularly at interfaces 99M and 99N, as well as bulk states in layer 827, enabling MISFET operation with low hysteresis and low fixed charge, resulting in very high performance.

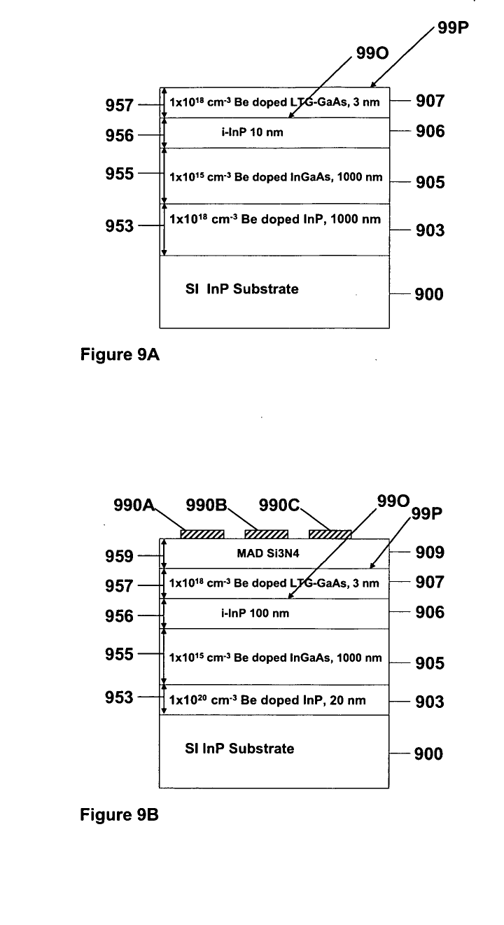

Reference is now made to FIG. 9A, showing an alternative embodiment of the invention. On a semi-insulating InP substrate 900 is deposited a p-type InP buffer layer 903 to a thickness 953 of 1000 nm doped with Be to 1×10¹⁸ cm⁻³. Next, the p-type InGaAs channel region 905 is grown lattice-matched to the InP substrate 900 to a thickness 955 of 1000 nm, doped with Be to a doping concentration of 1×10¹⁵ cm⁻³. Next, a lattice-matched, undoped InP channel barrier layer 906 is deposited to a thickness 956 of 10 nm. Finally, the LTG-GaAs surface passivation layer 907 is deposited to a thickness 957 of 3 nm, doped p-type with a Be doping density of about 1×10¹⁸ cm³, at a substrate temperature of 300° C. The interface between layers 906 and 907 is 990 and the top (exposed) surface is 99P.

Reference is now made to FIG. 9B, showing how the layer structure shown in FIG. 9A can be fabricated into a CCD photodetector. In accordance with the invention, the layer structure is removed from the MBE and a JVD Si₃N₄ layer 909 is deposited to a thickness 959 of 10 nm to form a semiconductor-insulator structure. Post deposition annealing to 500° C. for 60 seconds is used to lower the interface states to an acceptable value. Metal gates 990A, 990B, and 990C are used to control the charge transfer between the potential wells beneath each gate. In the manner of a conventional Si-based CCD, charge can transferred laterally (i.e. from beneath gate 990A to beneath gate 990B, and then from beneath gate 990B to 990C, and so forth), allowing a large array of pixels (where each pixel is defined by the region below gate 990A, 990B, 990C and so on) to be read out by shifting the collected charge sequentially from each pixel to adjacent pixels until it reaches the end of a row where it would be read out by a charge sensitive amplifier. The three pixels shown in FIG. 9B may be replicated to form large two dimensional InGaAs imaging CCD array capable of detecting wavelengths from the visible out to about 1.7 μm. Since the substrate is transparent, backside illumination may be used to eliminate shadowing effects.

We claim:

1. A method for passivating a surface of a first semiconductor material comprising the steps of (a) forming a thin anion-rich layer of a second semiconductor material adjacent to said first semiconductor material; (b) depositing a dielectric layer adjacent to said second semiconductor material; and (c) annealing the ensemble before, during, and/or after step (b).

2. The method of claim 1 wherein step (a) includes doping or implanting anions.

3. The method of claim 1 wherein said thin anion-rich layer of a second semiconductor material is less than 100 nm thick.

4. The method of claim 3 wherein said thin anion-rich layer of a second semiconductor material is less than 20 nm thick.

5. The method of claim 4 wherein said thin anion-rich layer of a second semiconductor material is less than 5 nm thick.

6. The method of claim 1 wherein said thin anion-rich layer contains at least 0.001% excess anions before step (c).

7. The method of claim 6 wherein said thin anion-rich layer contains at least 0.01% excess anions before step (c).

8. The method of claim 7 wherein said thin anion-rich layer contains at least 0.1% excess anions before step (c).

9. The method of claim 8 wherein said thin anion-rich layer contains at least 1% excess anions before step (c).

10. The method of claim 9 wherein said thin anion-rich layer contains at least 10% excess anions before step (c).

11. The method of claim 1 wherein said excess anions include arsenic.

12. The method of claim 1 wherein said thin anion-rich layer of a second semiconductor material combines one or more semiconductors from column III and one or more semiconductors from column V of the periodic table.

13. The method of claim 12 wherein said second semiconductor material is predominantly In_{y}Ga_{1-y}As (0<y<1).

14. The method of claim 13 wherein y is close to zero and said second semiconductor material is predominantly gallium arsenide.

15. The method of claim 12 where said second semiconductor material is predominantly InₓAl₁₋ₓAs (0.25<x<0.75).

16. A method of processing a semiconductor device including the steps of forming a second semiconductor material as a thin anion-rich layer on a first semiconductor material; and either depositing a dielectric layer on said second material and annealing said second material, or annealing said second material and depositing a dielectric layer on said second material.

17. A method in accordance with claim 16 wherein said second material before annealing contains an excess from 0.001% to 10% of anions and is thinner than 100 nm.

18. A method of reducing the net fixed charge in a region between a dielectric layer and a first semiconductor material to below 1012 cm⁻² in accordance with claim 16.

19. A method of reducing the net fixed charge in a region between a dielectric layer and a first semiconductor material to below 1011 cm⁻² in accordance with claim 16.

20. A method of reducing the surface recombination velocity in a region between a dielectric layer and a first semiconductor material to below 10⁵ cm per second in accordance with claim 16.

21. A method of reducing the surface recombination velocity in a region between a dielectric layer and a first semiconductor material to below 10⁴ cm per second in accordance with claim 16.

22. A method of making a field-effect transistor device in accordance with claim 16 wherein the gate insulator includes at least a portion of said dielectric layer.

23. A method of passivating a solar cell device wherein one or more active surfaces of said solar cell is processed in accordance with claim 16.

24. A method of passivating a bipolar transistor device wherein one or more regions of said bipolar transistor device is processed in accordance with claim 16.

25. A method of passivating a diode device wherein one or more regions of said diode device is processed in accordance with claim 16.

26. A method of passivating a charge-coupled device or CCD wherein one or more regions of said CCD is processed in accordance with claim 16.

27. A method of passivating a photodetector device wherein one or more regions of said photodetector device is processed in accordance with claim 16.

28. A field-effect transistor including a III-V compound semiconductor material with a net fixed charge density near a gate dielectric material below 1012 cm⁻² during operation.

29. The field-effect transistor of claim 28 with a net fixed charge density below 10¹¹ cm⁻² during operation.
